(19) United States
(12) Patent Application Publication
(10) Pub. No.: US 2008/0128303 A1
(43) Pub. Date: Jun. 5, 2008

(54) Device container assembly with adjustable retainers for a reticle

(75) Inventors: Alton H. Phillips, East Palo Alto, CA (US); Douglas C. Watson, Campbell, CA (US); Michael Binnard, Belmont, CA (US)

Correspondence Address: Roeder & Broder LLP, 5560 Chelsea Avenue, La Jolla, CA, 92037, US

(73) Assignee: Nikon Corporation, Tokyo (JP)

(21) Appl. No.: 11/634,786

(22) Filed: Dec. 5, 2006

(51) Int. Cl. G03F 9/00; B65D 85/38

(52) U.S. Cl. 206/316.1; 222/528; 430/5

(57) ABSTRACT

A device container assembly (30) for storing a reticle (26) includes a first container (246) and a device retainer assembly (248). The first container (246) encircles and encloses the reticle (26). The device retainer assembly (248) selectively couples the reticle to the first container (246). The device retainer assembly (248) can include an adjustable first device retainer (256) having a retainer section (280A) that is movable relative to the first container (246) between an engaged position (281A) in which the retainer section (280A) engages the reticle (26) and a disengaged position (281B) in which the retainer section (280A) does not engage the reticle (26). With this design, the device container assembly (30) can retain the reticle (26) in a secure fashion and the integrity of the reticle (26) is maintained by the device container assembly (30).

### BACKGROUND

Exposure apparatuses for semiconductor processing are commonly used to transfer images from a reticle onto a semiconductor wafer. The images transferred onto the wafer from the reticle are extremely small. Accordingly, the quality of the reticle influences the quality of the images transferred to the wafer. As a result thereof, a container assembly is often used to protect the reticle during shipping from the reticle writing facility to the wafer fabrication facility and/or at the wafer fabrication facility when the reticle is not being utilized.

One type of container assembly includes an inner container, an outer container and a restraint mechanism that constrains the reticle to inner container and that constrains the inner container to the outer container. Unfortunately, (i) if the reticle is constrained too loosely, the reticle will slide and generate particles, (ii) if the reticle is constrained too tightly, particles will generate during the constraint process, (iii) if the inner container is constrained too loosely, the inner container will slide and generate particles that may be transferred to the reticle, and (iv) if the inner container is constrained too tightly, particles will generate during the constraint process that may be transferred to the reticle.

### SUMMARY

The present invention is directed to a device container assembly for storing a device. In one embodiment, the device container assembly includes a first container and a device retainer assembly. The first container encircles and encloses the device. The device retainer assembly selectively couples the device to the first container. In this embodiment, the device retainer assembly includes an adjustable first device retainer having a retainer section that is movable relative to the first container between an engaged position in which the retainer section engages the device and a disengaged position in which the retainer section does not engage the device. With this design, in certain embodiments, the device container assembly can retain the device in a secure fashion. As a result thereof, the integrity of the device is maintained by the device container assembly.

In one embodiment, the first device retainer includes a retainer lock that selectively locks the retainer section in the engaged position and in the disengaged position.

Further, in one embodiment, the first device retainer includes a retainer actuator that moves the retainer section between the engaged position and the disengaged position. For example, the retainer actuator can be operated in a force mode.

Moreover, the retainer section can engage the device with substantially normal contact. As a result thereof, in certain embodiments, there is no sliding contact between the retainer section and the device and there is less particle generation.

In certain embodiments, the retainer section is moved between the positions with the first container encircling the device.

Additionally, the device retainer assembly can include an adjustable second device retainer having a retainer section that is movable relative to the first container between an engaged position in which the retainer section engages the device and a disengaged position in which the retainer section does not engage the device. In one embodiment, the retainer section of the second device retainer is substantially aligned with and opposite from the retainer section of the first device retainer. In another embodiment, the retainer section of the second device retainer is substantially parallel to and spaced apart from the retainer section of the first device retainer. In yet another embodiment, the retainer section of the second device retainer is substantially perpendicular to and spaced apart from the retainer section of the first device retainer.

In certain embodiments, the device retainer assembly includes six device retainer pairs that cooperate to secure the device in a kinematic fashion.

The device container assembly can also include (i) a second container that encircles the first container, and (ii) a container retainer assembly that selectively couples the first container to the second container. In this embodiment, the container retainer assembly includes an adjustable first container retainer having a retainer section that is movable relative to the second container between an engaged position in which the retainer section engages the first container and a disengaged position in which the retainer section does not engage the first container. Further, in this embodiment, the first container retainer can include a retainer lock that selectively locks the retainer section in the engaged position and in the disengaged position. Additionally, in this embodiment, the first container retainer can include a retainer actuator that moves the retainer section between the engaged position and the disengaged position. Further, the device container assembly can include six container retainer pairs that cooperate to secure the first container in a kinematic fashion.

Further, the present invention is directed to (i) a combination including a reticle and the device container assembly, (ii) an exposure apparatus for transferring an image to an object, (iii) a method for manufacturing an object, and (iv) a method for storing a device.

### BRIEF DESCRIPTION OF THE DRAWINGS

The novel features of this invention, as well as the invention itself, both as to its structure and its operation, will be best understood from the accompanying drawings, taken in conjunction with the accompanying description, in which similar reference characters refer to similar parts, and in which:

FIG. 1 is a schematic illustration of an exposure apparatus having features of the present invention;

FIG. 2A is a perspective view of a combination including a device container assembly and a reticle;

FIG. 2B is a cut-way view of the reticle and the device container assembly of FIG. 2A;

FIG. 2C is a simplified illustration of a retainer lock having features of the present invention;

FIG. 2D is a top perspective view of the device with a simplified illustration of the forces applied to the device;

FIG. 2E is a top perspective view of the first container with a simplified illustration of the forces applied to the first container;

FIGS. 2F-2H are cut-way views of the reticle and the device container assembly with the device container assembly in different stages of assembly;

FIG. 3 is cut-way view of the reticle and another embodiment of the device container assembly;

FIG. 4A is a flow chart that outlines a process for manufacturing an object in accordance with the present invention; and

FIG. 4B is a flow chart that outlines object processing in more detail.

### DESCRIPTION

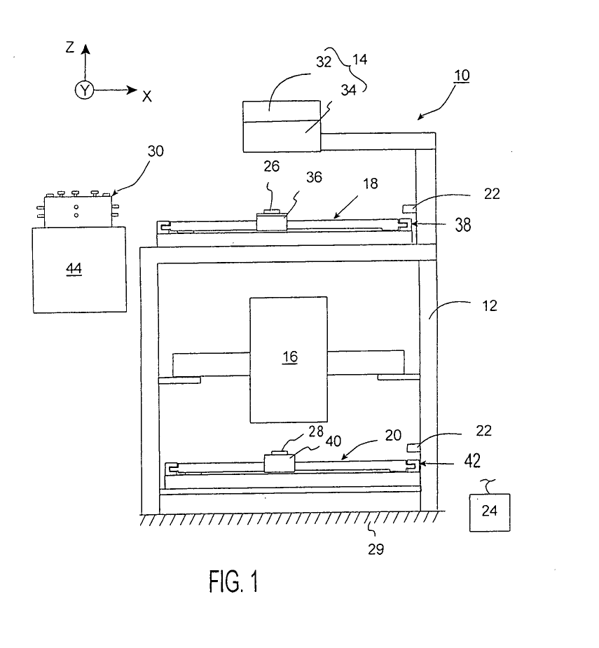

FIG. 1 is a schematic illustration of a precision assembly, namely an exposure apparatus (lithography apparatus) 10 that includes an apparatus frame 12, an illumination system 14 (irradiation apparatus), an optical assembly 16, a first (reticle) stage assembly 18, a second (wafer) stage assembly 20, a measurement system 22, and a control system 24. The exposure apparatus 10 illustrated in FIG. 1 is particularly useful as a lithographic device that transfers a pattern (not shown) of an integrated circuit from a first device 26, e.g. a reticle onto a second device 28, e.g. a semiconductor wafer. The exposure apparatus 10 mounts to a mounting base 29, e.g., the ground, a base, or floor or some other supporting structure.

A number of Figures include an orientation system that illustrates an X axis, a Y axis that is orthogonal to the X axis and a Z axis that is orthogonal to the X and Y axes. It should be noted that these axes can also be referred to as the first, second and third axes.

FIG. 1 also illustrates a device container assembly 30 that can be used to safely store the reticle 26 when the reticle 26 is not being used. For example, the device container assembly 30 can store the reticle 26 when the reticle 26 is transported from the reticle writing facility to the wafer fabrication facility. In certain embodiments, the device container assembly 30 securely retains the reticle 26 and inhibits relative movement between the reticle 26 and the device container assembly 30. As a result thereof, the device container assembly 30 can protect the reticle 26 and reduce the amount of particles that are generated within the device container assembly 30 when the reticle 26 is not in use. The device container assembly 30 is described in more detail below.

There are a number of different types of lithographic devices. For example, the exposure apparatus 10 can be used as a scanning type photolithography system that exposes the pattern from the reticle 26 onto the wafer 28 with the reticle 26 and the wafer 28 moving synchronously. In a scanning type lithographic device, the reticle 26 is moved perpendicularly to an optical axis of the optical assembly 16 by the reticle stage assembly 18 and the wafer 28 is moved perpendicularly to the optical axis of the optical assembly 16 by the wafer stage assembly 20. Scanning of the reticle 26 and the wafer 28 occurs while the reticle 26 and the wafer 28 are moving synchronously.

Alternatively, the exposure apparatus 10 can be a step-and-repeat type lithography system that exposes the reticle 26 while the reticle 26 and the wafer 28 are stationary. In the step and repeat process, the wafer 28 is in a constant position relative to the reticle 26 and the optical assembly 16 during the exposure of an individual field. Subsequently, between consecutive exposure steps, the wafer 28 is consecutively moved with the wafer stage assembly 20 perpendicularly to the optical axis of the optical assembly 16 so that the next field of the wafer 28 is brought into position relative to the optical assembly 16 and the reticle 26 for exposure. Following this process, the images on the reticle 26 are sequentially exposed onto the fields of the wafer 28, and then the next field of the wafer 28 is brought into position relative to the optical assembly 16 and the reticle 26.

However, the use of the exposure apparatus 10 provided herein is not limited to a photolithography system for semiconductor manufacturing. For example, the exposure apparatus 10 can be a LCD photolithography system that exposes a liquid crystal display pattern from a mask onto a rectangular glass plate. Further, the present invention can also be applied to a proximity photolithography system that exposes a mask pattern from a mask to a substrate with the mask located close to the substrate without the use of a lens assembly.

The apparatus frame 12 is rigid and supports the components of the exposure apparatus 10. The apparatus frame 12 illustrated in FIG. 1 supports the stage assemblies 18, 20, the optical assembly 16 and the illumination system 14 above the mounting base 29.

In one embodiment, the illumination system 14 includes an illumination source 32 and an illumination optical assembly 34. The illumination source 32 emits a beam (irradiation) of light energy. The illumination optical assembly 34 guides the beam of light energy from the illumination source 32 to the optical assembly 16. The beam illuminates selectively different portions of the reticle 26 and exposes the wafer 28. In FIG. 1, the illumination source 32 is illustrated as being supported above the reticle stage assembly 18. However, the illumination source 32 can be secured to one of the sides of the apparatus frame 12 and the energy beam from the illumination source 32 is directed at the bottom of the reticle 26 with the illumination optical assembly 34.

The illumination source 32 can be a g-line source (436 nm), an i-line source (365 nm), a KrF excimer laser (248 nm), an ArF excimer laser (193 nm) or a F₂ laser (157 nm). Alternatively, the illumination source 32 can generate charged particle beams such as an x-ray or an electron beam. For instance, in the case where an electron beam is used, thermionic emission type lanthanum hexaboride (LaB₆) or tantalum (Ta) can be used as a cathode for an electron gun. Furthermore, in the case where an electron beam is used, the structure could be such that either a mask is used or a pattern can be directly formed on a substrate without the use of a mask.

The optical assembly 16 projects and/or focuses the light passing through the reticle 26 to the wafer 28. Depending upon the design of the exposure apparatus 10, the optical assembly 16 can magnify or reduce the image illuminated on the reticle 26. The optical assembly 16 need not be limited to a reduction system. It could also be a 1× or magnification system.

When far ultra-violet rays such as the excimer laser is used, glass materials such as quartz and fluorite that transmit far ultra-violet rays can be used in the optical assembly 16. When the F₂ type laser or x-ray is used, the optical assembly 16 can be either catadioptric or refractive (a reticle should also preferably be a reflective type), and when an electron beam is used, electron optics can consist of electron lenses and deflectors. The optical path for the electron beams should be in a vacuum.

Also, with an exposure device that employs vacuum ultra-violet radiation (VUV) of wavelength 200 nm or lower, use of the catadioptric type optical system can be considered. Examples of the catadioptric type of optical system include the disclosure Japan Patent Application Disclosure No.8-171054 published in the Official Gazette for Laid-Open Patent Applications and its counterpart U.S. Pat. No. 5,668,672, as well as Japan Patent Application Disclosure No.10-20195 and its counterpart U.S. Pat. No. 5,835,275. In these cases, the reflecting optical device can be a catadioptric optical system incorporating a beam splitter and concave mirror. Japan Patent Application Disclosure No.8-334695 published in the Official Gazette for Laid-Open Patent Applications and its counterpart U.S. Pat. No. 5,689,377 as well as Japan Patent Application Disclosure No.10-3039 and its counterpart U.S. patent application Ser. No. 873,605 (Application Date: Jun. 12, 1997) also use a reflecting-refracting type of optical system incorporating a concave mirror, etc., but without a beam splitter, and can also be employed with this invention. As far as is permitted, the disclosures in the above-mentioned U.S. patents, as well as the Japan patent applications published in the Official Gazette for Laid-Open Patent Applications are incorporated herein by reference.

The reticle stage assembly 18 holds and positions the reticle 26 relative to the optical assembly 16 and the wafer 28. Somewhat similarly, the wafer stage assembly 20 holds and positions the wafer 28 with respect to the projected image of the illuminated portions of the reticle 26. The design of each stage assembly 18, 20 can be varied to suit the movement requirements of the exposure apparatus 10. In FIG. 1, the reticle stage assembly 18 includes a first (reticle) stage 36 that retains the reticle 26 and a first (reticle) mover assembly 38 that moves and positions the reticle stage 36 and the reticle 26 relative to the rest of the exposure apparatus 10.

Somewhat similarly, the wafer stage assembly 20 includes a second (wafer) stage 40 that retains the wafer 28 and a second (wafer) mover assembly 42 that moves and positions the wafer stage 40 and the wafer 28 relative to the rest of the exposure apparatus 10.

Each mover assembly 38, 42 can include one or more linear motors, rotary motors, voice coil motors, electromagnetic movers, planar motors, or some other type of force mover.

Further, in photolithography systems, when linear motors (see U.S. Pat. Nos. 5,623,853 or 5,528,118) are used in a first stage or a second stage, the linear motors can be either an air levitation type employing air bearings or a magnetic levitation type using Lorentz force or reactance force. As far as is permitted, the disclosures in U.S. Pat. Nos. 5,623,853 and 5,528,118 are incorporated herein by reference.

Alternatively, one of the stages could be driven by a planar motor, which drives the stage by an electromagnetic force generated by a magnet unit having two-dimensionally arranged magnets and an armature coil unit having two-dimensionally arranged coils in facing positions. With this type of driving system, either the magnet unit or the armature coil unit is connected to the stage and the other unit is mounted on the moving plane side of the stage.

Movement of the stages as described above generates reaction forces that can affect performance of the photolithography system. Reaction forces generated by the wafer (substrate) stage motion can be mechanically transferred to the floor (ground) by use of a frame member as described in U.S. Pat. No. 5,528,100 and published Japanese Patent Application Disclosure No. 8-136475. Additionally, reaction forces generated by the reticle (mask) stage motion can be mechanically transferred to the floor (ground) by use of a frame member as described in U.S. Pat. No. 5,874,820 and published Japanese Patent Application Disclosure No. 8-330224. As far as is permitted, the disclosures in U.S. Pat. Nos. 5,528,100 and 5,874,820 and Japanese Patent Application Disclosure No. 8-330224 are incorporated herein by reference.

The measurement system 22 monitors movement of (i) the reticle stage 36 and the reticle 26 relative to the optical assembly 16 or some other reference, and (ii) the wafer stage 40 and the wafer 28 relative to the optical assembly 16 or some other reference. With this information, the control system 24 can control the reticle stage assembly 18 to precisely position the reticle 26 and the wafer stage assembly 20 to precisely position the wafer 28. For example, the measurement system 22 can utilize multiple laser interferometers, encoders, and/or other measuring devices.

The control system 24 is electrically connected to the reticle stage assembly 18, the wafer stage assembly 20, and the measurement system 22. The control system 24 receives information from the measurement system 22 and controls the stage assemblies 18, 20 to precisely position the reticle 26 and the wafer 28. The control system 24 can include one or more processors and circuits.

A photolithography system according to the embodiments described herein can be built by assembling various subsystems, including each element listed in the appended claims, in such a manner that prescribed mechanical accuracy, electrical accuracy, and optical accuracy are maintained. In order to maintain the various accuracies, prior to and following assembly, every optical system is adjusted to achieve its optical accuracy. Similarly, every mechanical system and every electrical system are adjusted to achieve their respective mechanical and electrical accuracies. The process of assembling each subsystem into a photolithography system includes mechanical interfaces, electrical circuit wiring connections and air pressure plumbing connections between each subsystem. There is also a process where each subsystem is assembled prior to assembling a photolithography system from the various subsystems. Once a photolithography system is assembled using the various subsystems, a total adjustment is performed to make sure that accuracy is maintained in the complete photolithography system. Additionally, it is desirable to manufacture an exposure system in a clean room where the temperature and cleanliness are controlled.

This invention can be utilized in an immersion type exposure apparatus with taking suitable measures for a liquid. For example, PCT Patent Application WO 99/49504 discloses an exposure apparatus in which a liquid is supplied to the space between a substrate (wafer) and a projection lens system in exposure process. As far as is permitted, the disclosures in WO 99/49504 are incorporated herein by reference.

Further, this invention can be utilized in an exposure apparatus that comprises two or more substrate and/or reticle stages. In such apparatus, the additional stage may be used in parallel or preparatory steps while the other stage is being used for exposing. Such a multiple stage exposure apparatus are described, for example, in Japan Patent Application Disclosure No. 10-163099 as well as Japan Patent Application Disclosure No. 10-214783 and its counterparts U.S. Pat. No. 6,341,007, No. 6,400,441, No. 6,549,269, and No. 6,590,634. Also it is described in Japan Patent Application Disclosure No. 2000-505958 and its counterparts U.S. Pat. No. 5,969,411 as well as U.S. Pat. No. 6,208,407. As far as is permitted, the disclosures in the above-mentioned U.S. Patents, as well as the Japan Patent Applications, are incorporated herein by reference.

This invention can be utilized in an exposure apparatus that has a movable stage retaining a substrate (wafer) for exposing it, and a stage having various sensors or measurement tools for measuring, as described in Japan Patent Application Disclosure 11-135400. As far as is permitted, the disclosures in the above-mentioned Japan patent application are incorporated herein by reference.

FIG. 1 also illustrates that the exposure apparatus 10 can include a device loader 44 (illustrated as a box) that can be used to move the reticle 26 between the reticle stage 36 and the device container assembly 30 and/or to open and close the device container assembly 30. For example, the device loader 44 can include one or more robotic arms (not shown) that can be controlled to perform these tasks.

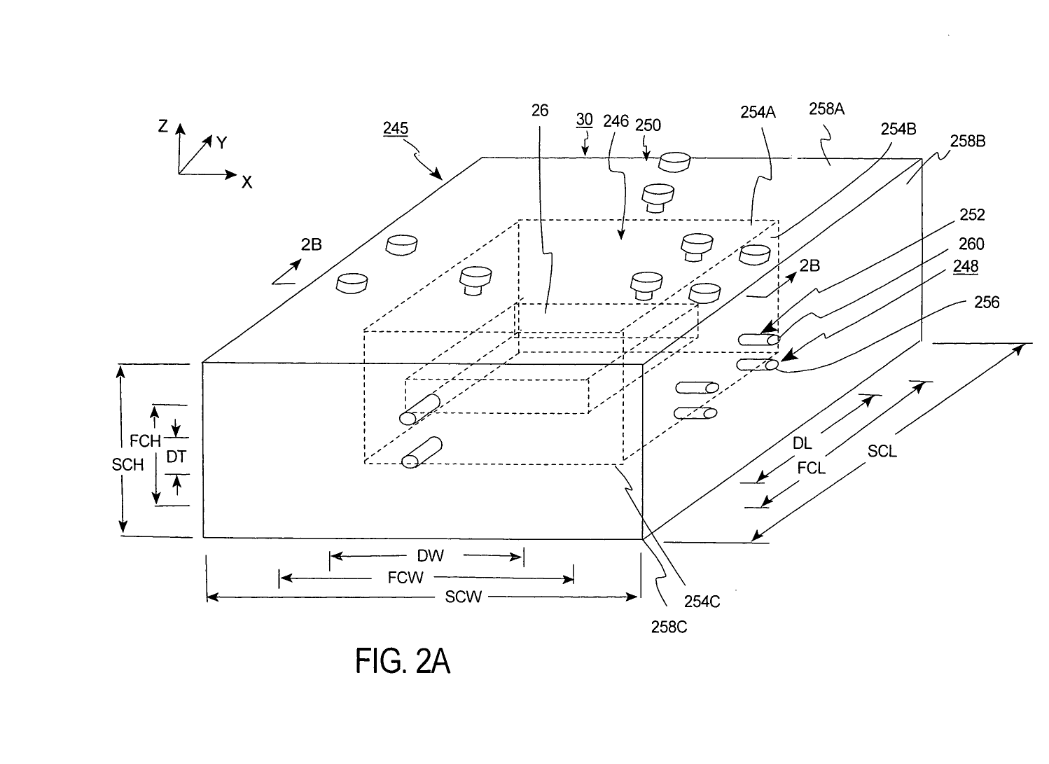

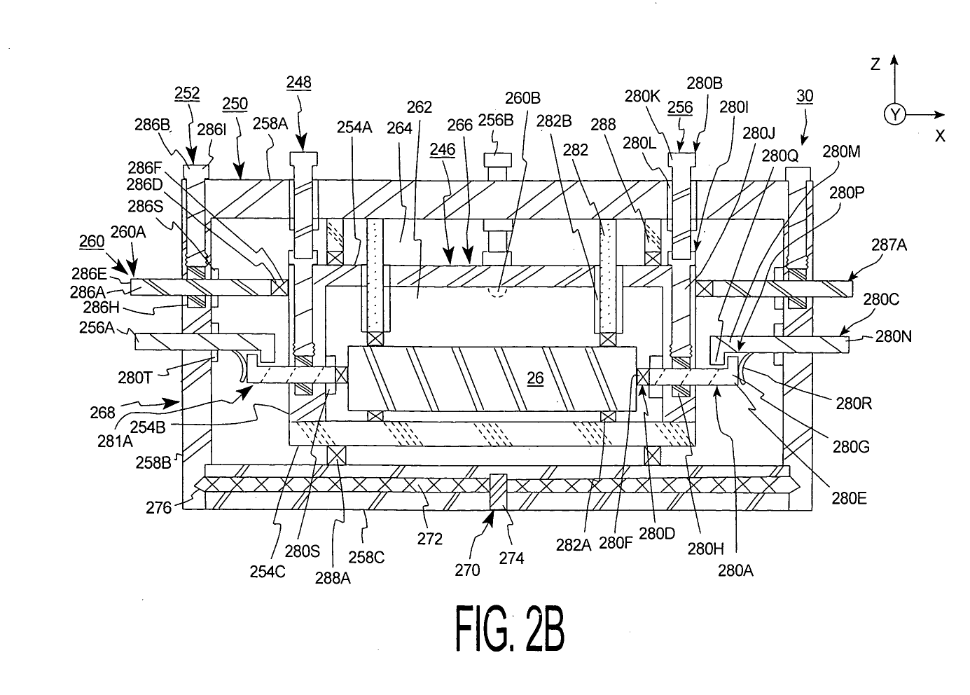

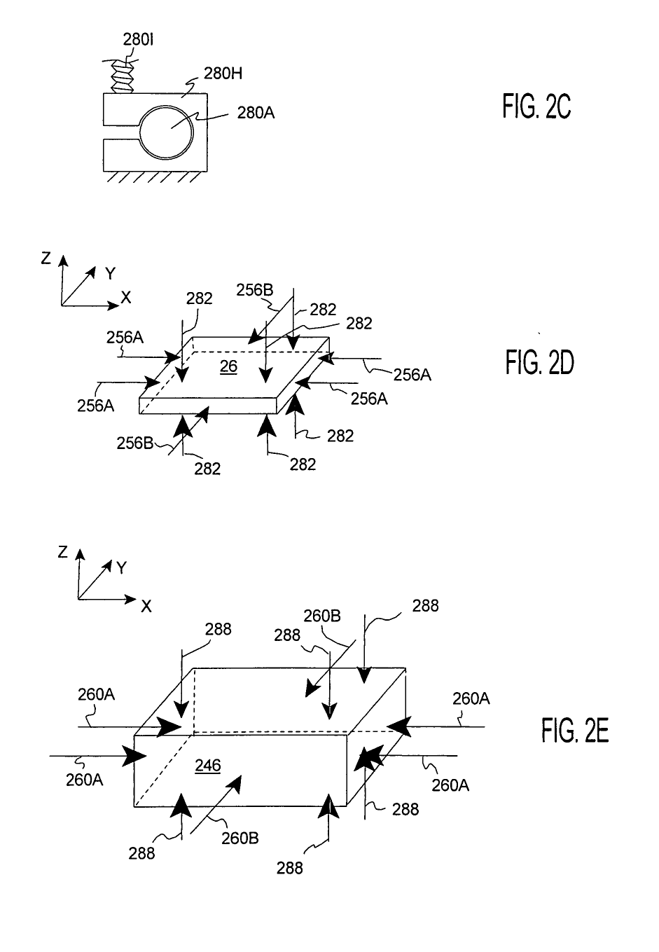

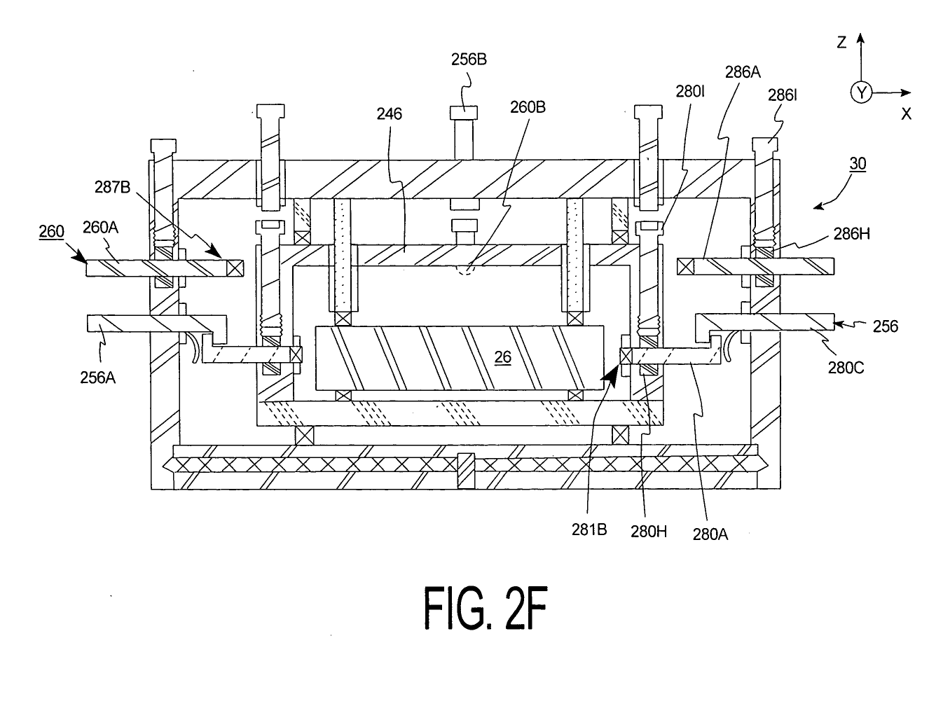

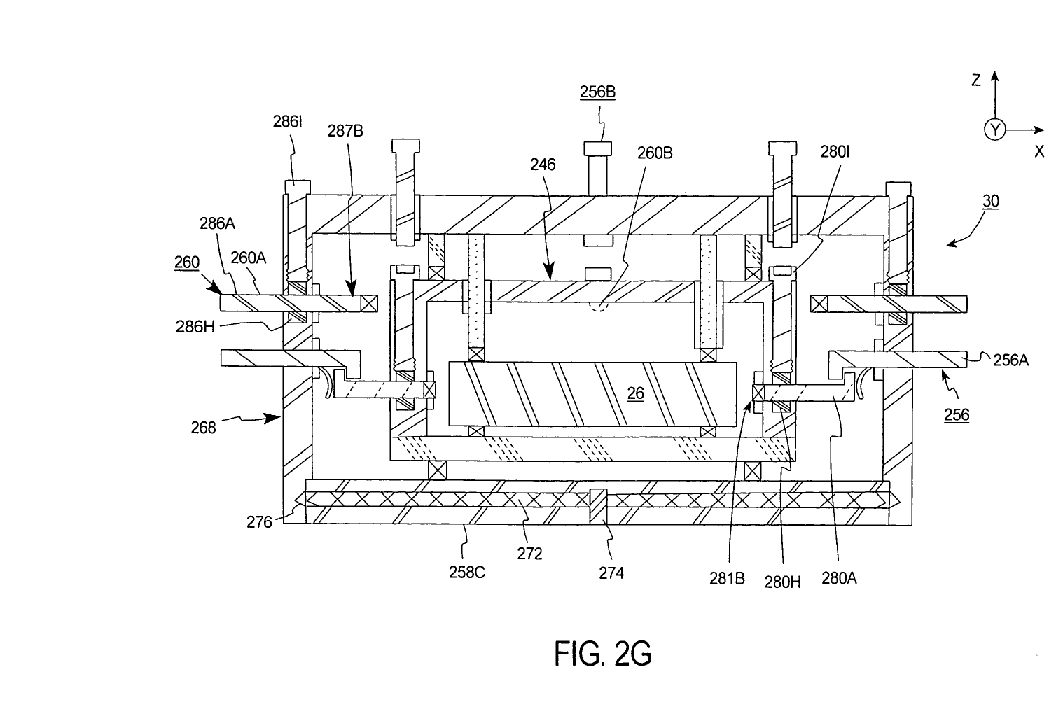

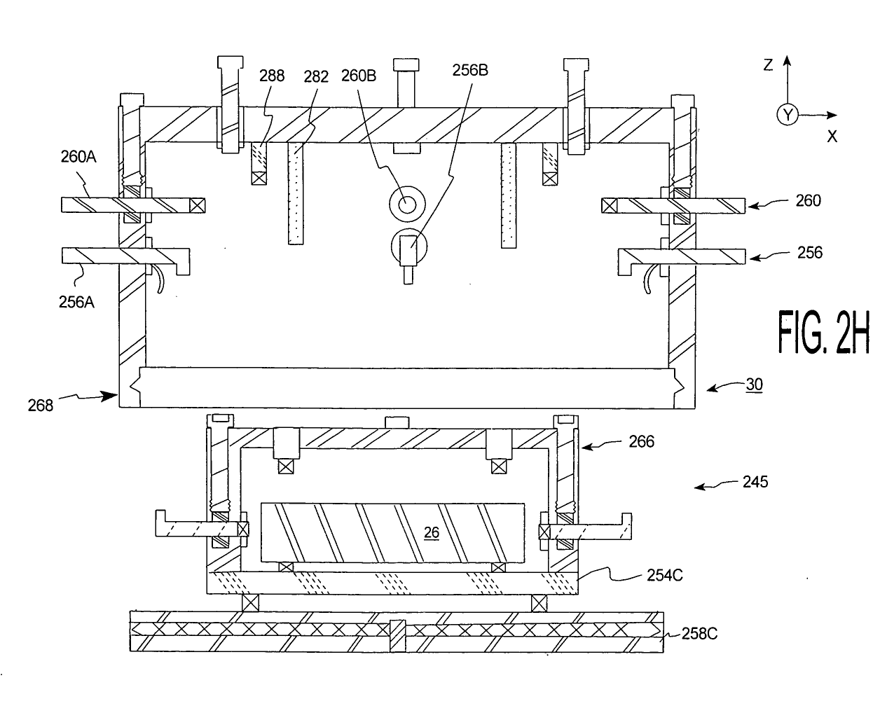

FIG. 2A is a perspective view of a combination 245 that includes the device 26 (illustrated in phantom) and one embodiment of the device container assembly 30. In one embodiment, the device container assembly 30 includes an inner, first container 246 (illustrated in phantom in FIG. 2A), a device retainer assembly 248, an outer, second container 250, and a container retainer assembly 252. The design of each of these components can be varied pursuant to the teachings provided herein. It should be noted that either the inner or the outer container can be referred to as the first or second container and that these terms are used for ease of discussion.

The first container 246 provides a structure for protecting and storing the device 26 when the device 26 is not in use. The size, shape and design of the first container 246 can be varied to suit the design of the device 26. In FIG. 2A, the device 26 is a reticle that is generally rectangular shaped, has a device width “DW” of approximately 6 inches, has a device length “DL” of approximately 6 inches, and a device thickness “DT” of approximately ¼ inch. In one non-exclusive embodiment, the first container 246 is generally rectangular box shaped, has a first container width “FCW” of approximately two hundred millimeters, a first container length “FCL” of approximately two hundred millimeters, and a first container height “FCH” of approximately fifty millimeters. Alternatively, the first container 246 can be another size and/or shape.

In FIG. 2A, the first container 246 includes a top wall 254A, four side walls 254B, and a bottom wall 254C that is opposite and spaced apart from the top wall 254A. In this embodiment, each of the walls 254A, 254B, 254C is generally flat plate shaped and is made of a rigid material. For example, suitable materials for the walls 254A, 254B, 254C include aluminum, polycarbonate, or stainless steel. As non-exclusive examples, each of the walls 254A, 254B, 254C can have a thickness of approximately 3, 5, 7, or 10 mm.

The device retainer assembly 248 retains the device 26 and securely couples the device 26 to the first container 246. In certain embodiments, the device retainer assembly 248 includes one or more adjustable device retainers 256 that retain the device 26 in a fashion that inhibits relative movement of between the device 26 and the first container 246. This protects the reticle 26 and reduces the likelihood of particle generation caused by relative movement between the device 26 and the first container 246 during shipping or storage of the device 26.

The second container 250 provides additionally structure for protecting the device 26 when the device 26 is not in use. The size, shape and design of the second container 250 can be varied. In FIG. 2A, the second container 250 encircles and encloses the first container 246. In one, non-exclusive embodiment, the second container 250 is generally rectangular box shaped, has a second container width “SCW” of approximately two hundred and fifty millimeters, a second container length “SCL” of approximately two hundred and fifty millimeters, and a second container height “SCH” of approximately eighty millimeters. Alternatively, the second container 250 can be another size and/or shape.

In FIG. 2A, the second container 250 includes a top wall 258A, four side walls 258B, and a bottom wall 258C that is opposite and spaced apart from the top wall 258A. In this embodiment, each of the walls 258A, 258B, 258C is generally flat plate shaped and is made of a rigid material. For example, suitable materials for the walls 258A, 258B, 258C include aluminum, polycarbonate, or stainless steel. As non-exclusive examples, each of the walls 258A, 258B, 258C can have a thickness of approximately 3, 5, 7, or 10 mm.

The container retainer assembly 252 retains the first container 246 and securely couples the first container 246 to the second container 250. In certain embodiments, the container retainer assembly 252 includes one or more adjustable container retainers 260 that retain the first container 246 in a fashion that inhibits relative movement of between the first container 246 and the second container 250. This reduces the likelihood of particle generation and damage to the device 26 during shipping or storage of the device 26.

It should be noted that the device retainers 256 and/or container retainers 260 can also be referred to as a first retainer or a second retainer.

FIG. 2B is a cut-away view of the device container assembly 30 and the reticle 26 taken on line 2B-2B in FIG. 2A. FIG. 2B illustrates that the first container 246 defines a generally rectangular shaped first chamber 262 that receives, encloses, and encircles the reticle 26. Further, the second container 250 defines a generally rectangular shaped second chamber 264 that receives, encloses, and encircles the first container 246 and the reticle 26.

Moreover, FIG. 2B illustrates that the first container 246 can include a first removable section 266 that can be selectively removed (after the second container 250 has been disassembled) to allow for the device 26 to be removed from the first container 246. The design of the first removable section 266 can vary. In FIG. 2B, the top wall 254A and the four side walls 254B make up the first removable section 266 that can be removed from the bottom wall 254C. Alternatively, the first removable section 266 can have another design.

Somewhat similarly, FIG. 2B illustrates that the second container 250 can include a second removable section 268 that can be selectively removed to allow for the first container 246 and the device 26 to be removed. The design of the second removable section 268 can vary. In FIG. 2B, the top wall 258A and the four side walls 258B make up the second removable section 268 that can be removed from the bottom wall 258C. Alternatively, the second removable section 268 can have another design.

It should be noted that with the design illustrated in FIG. 2B, the first removable section 266 does not have to be fixedly locked to the bottom wall 254C. Alternatively, a latch (not shown) can be used to selectively lock the first removable section 266 to the bottom wall 254C.

In contrast, the second container 250 illustrated in FIG. 2B includes a latch 270 that selectively latches the second removable section 268 to the rest of the second container 250. The design of the latch 270 can vary. In FIG. 2B, the latch 270 includes a pair of opposed lock pins 272 positioned in the bottom wall 258C, a pin mover 274 (illustrated as a square) positioned in the bottom wall 258C, and a pair of slots 276 positioned in the side walls 258B. In this embodiment, rotation of the pin, mover 274 in one direction causes both lock pins 272 to move outward so that the lock pins 272 engage the corresponding slots 276 in the second removable section 268 to secure the second removable section 268 to the bottom wall 258C. Further, rotation of the pin mover 274 in the opposite direction causes both lock pins 272 to move inward so that the lock pins 272 do not engage the corresponding slots 276 in the second removable section 268 and the second removable section 268 can be moved away from the bottom wall 258C.

Additionally, FIG. 2B illustrates that the device retainer assembly 248 and the container retainer assembly 252 in more detail. In one embodiment, the device retainer assembly 248 includes (i) two pairs of opposed, adjustable X device retainers 256A (only one pair is illustrated in FIG. 2B) that inhibit movement of the device 26 relative to the first container 246 along the X axis, and about the Z axis; (ii) one pair of opposed, adjustable Y device retainers 256B (only one is illustrated in FIG. 2B) that inhibits movement of the device 26 relative to the first container 246 along the Y axis; and (iii) three pairs of opposed, Z device retainers 282 (only two pairs are illustrated in FIG. 2B) that inhibit movement of the device 26 relative to the first container 246 and/or the second container 250 along the Z axis, about the X axis and about the Y axis. It should be noted that one or more of adjustable X device retainers 256A and/or the adjustable Y device retainers 256B can also be referred to as the adjustable device retainer 256.

The design of each of the adjustable device retainers 256 can vary. In FIG. 2B, each of the adjustable device retainers 256 includes a retainer section 280A, a retainer lock 280B, and a retainer mover 280C. Alternatively, one or more of the adjustable device retainers 256 can have another design. For example, one or more of the adjustable device retainers 256 can designed without the retainer mover 280C.

In one embodiment, for each of the adjustable device retainers 256, the retainer section 280A extends between the first container 246 and the device 26, and the retainer section 280A is generally right cylindrical beam shaped and extends through a container aperture in one of the side walls 254B of the first container 246. In one embodiment, the side wall 254B guides the movement of the retainer section 280A. Further, in FIG. 2B, the retainer section 280A includes a distal end 280D that engages the device 26 and a proximal end 280E that is positioned outside the first container 246. Moreover, in FIG. 2B, the distal end 280D can include a contact area 280F that reduces the likelihood that the distal end 280D will damage the device 26, and the proximal end 280E can include a catch 280G that allows for the proximal end 280E to be selectively engaged by the retainer mover 280C. For example, the contact area 280F can include a piece of resilient material, and the catch 280G can include a lip that extends away (upward in FIG. 2B) from the rest of the retainer section 280A.

In certain embodiments, the retainer section 280A is selectively movable between an engaged position 281A in which the retainer section 280A engages the reticle 26 and a disengaged position 281B (illustrated in FIG. 2F) in which the retainer section 280A does not engage the reticle 26.

The retainer lock 280B selectively locks the retainer section 280A to the first container 246 and selectively allows the retainer section 280A to be moved relative to the first container 246 and the reticle 26. Stated in another fashion, the retainer lock 280B allows the retainer section 280A to be moved between the engaged position 281A and the disengaged position 281B and subsequently locked in place at either position. With this design, the retainer sections 280A are maintained in the engaged position 281A during shipping, and the retainer lock 280B provides high stiffness so that no shifting or slipping occurs when the reticle 26 and the container assembly 30 experience high accelerations.

The design of the retainer lock 280B can vary. In one embodiment, the retainer lock 280B does not require power, air of other utilities when in locked state. As a result thereof, the reticle 26 can be securely retained during shipping or storage without external power.

In FIG. 2B, the retainer lock 280B includes a clamp 280H and clamp mover 280I that are secured to the first container 246. FIG. 2C is a simplified illustration of the retainer section 280A, the clamp 280H and a portion of the clamp mover 280I. In this embodiment, the clamp 280H is a collar that encircles the retainer section 280A. Further, in this embodiment, rotation of the clamp mover 280I in one direction causes the clamp mover 280I to urge a portion of the collar downward so that the collar tightly grips the retainer section 280A, and rotation of the clamp mover 280I in the opposite direction allows a portion of the collar to move upward so that the collar does not tightly grip the retainer section 280A.

Referring back to FIG. 2B, the clamp mover 280I can include an externally threaded member 280J, e.g. a bolt, that is threaded into the first container 246 and a connector member 280K that extends through the second container 250. In this embodiment, the connector member 280K can be used to selectively engage the head of the threaded member 280J. With this design, the threaded member 280J can be rotated using the connector member 280K when the second container 250 is encircling the first container 246. Additionally, the clamp mover 280I can include a connector seal 280L that seals the connector member 280K to the second container 250 and allows the connector member 280K to move relative to the second container 250. For example, the connector seal 280L can be a bellows type seal.

In one embodiment, for each of the adjustable device retainers 256, the retainer mover 280C extends between the second container 250 and the retainer section 280A, and the retainer mover 280C is generally right cylindrical beam shaped and extends through a container aperture in the side wall 258B of the second container 250. In one embodiment, the side wall 258B guides the movement of the retainer mover 280C. Further, in FIG. 2B, the retainer mover 280C includes a distal end 280M that selectively engages the retainer section 280A and a proximal end 280N that is positioned outside the second container 250. Moreover, in FIG. 2B, the distal end 280M can include a second catch 280P that allows the retainer mover 280C to selectively engage the first catch 280G of the retainer section 280A. In one embodiment, the second catch 280P can include a rigid lip 280Q and a spaced apart flexible lip 280R that each extends away (downward in FIG. 2B) from the rest of the retainer mover 280C. With this design, the retainer mover 280C can be used to manually move and position the retainer section 280A, and the flexible lip 280R can regulate the amount of force transferred from the retainer mover 280C to the retainer section 280A when the retainer section 280A is moved towards the reticle 26.

Additionally, in one embodiment, one or more of the adjustable device retainers 256 can include (i) a first retainer seal 280S that seals the retainer section 280A to the first container 246 and allows the retainer section 280A to move relative to the first container 246 and/or (ii) a second retainer seal 280T that seals the retainer mover 280C to the second container 250 and allows the retainer mover 280C to move relative to the second container 250. For example, the each retainer seal 280S, 280T can be a bellows type seal.

Moreover, one or more of the adjustable device retainers 256 can include a second retainer lock (not shown) that can be used to selectively lock the retainer mover 280C to the second container 250.

It should be noted that one or more of the adjustable device retainers 256 can be replaced with a fixed device retainer (not shown) that is fixedly secured to the first container 246 or the second container 250.

The design of each of the Z device retainers 282 can vary. In FIG. 2B, (i) each of the Z device retainers 282 that is above the device 26 is a fixed, right cylindrical shaped beam that cantilevers and extends downward from the second container 250 through the first container 246; and (ii) each of the Z device retainers 282 that is below the device 26 is a standoff that extends upward from the bottom wall 258C of the first container 246. In one embodiment, one or more of the Z device retainers 282 includes a contact area 282A that reduces the likelihood that the distal end will damage the device 26. For example, the contact area 282A can include a piece of resilient material.

Additionally, one or more of the upper Z device retainers 282 can include a retainer seal 282B that seals the respective Z device retainer 282 to the first container 246 and allows the Z device retainer 282 to move relative to the first container 246. For example, the retainer seal 282B can be a bellows type seal. In one embodiment, the contact 282A of each upper Z device retainer 282 is secured to the respective retainer seal 282B.

It should be noted that one or more of the fixed Z device retainers 282 can be replaced with an adjustable Z device retainer (not shown) that is somewhat similar to the adjustable device retainers 256 described above.

FIG. 2D is a top perspective view of the device 26 and a simplified illustration of the forces imparted on the device 26 by (i) the adjustable X device retainers 256A (illustrated as arrows in FIG. 2D) that inhibit movement of the device 26 relative to the first container 246 (not shown in FIG. 2D) along the X axis, and about the Z axis; (ii) the adjustable Y device retainers 256B (illustrated as arrows in FIG. 2D) that inhibit movement of the device 26 relative to the first container 246 along the Y axis; and (iii) the Z device retainers 282 (illustrated as arrows in FIG. 2D) along the Z axis, about the X axis and about the Y axis.

It should be noted that the X device retainers 256A of each pair are aligned along the X axis, the pair of Y device retainers 256B are aligned along the Y axis, and the Z device retainers 282 of each pair are aligned along the Z axis. Further, (i) the X device retainers 256A are perpendicular to the Y device retainers 256B and the Z device retainers 282 and (ii) the Y device retainers 256B are perpendicular to the Z device retainers 282.

Additionally, in this embodiment, three pairs of device retainers 256A, 256B constrain movement of the device 26 in the horizontal plane so that the device 26 does not move horizontally. Further, three pairs of device retainers 282 constrain movement of the device 26 in the vertical plane so that the device 26 does not move vertically. Alternatively, additionally pairs of device retainers 256A, 256B, 282 can be utilized to decrease the contact force while increasing stiffness and decreasing the required force of the retainer locks 280B.

Moreover, movement of each retainer section 280A (illustrated in FIG. 2B) from the disengaged position 281B to the engaged position 281A occurs substantially perpendicular to the surface of the device 26 in which that retainer section 280A engages. Stated in another fashion, each retainer section 280A engages the device 26 with normal contact only (no sliding contact). This reduces the amount of particle generation when the retainer sections 280A engage the device 26.

Further, with the arrangement illustrated in FIG. 2D, the device 26 is held by six pairs of retainers 256A, 256B, 282 that are arranged in a kinematic manner. This reduces the likelihood of particle generation caused by relative movement between the device 26 and the first container 246. Moreover, the amount of force applied by the adjustable device retainers 256A, 256B can be precisely controlled so that the device 26 is not retained too loosely or too tightly. This further reduces the likelihood of particle generation. Furthermore, because the restraining force does not depend on the friction between the device 26 and the retainers 256A, 256B, 282, relatively low restraining force can be used and there is less particle generation.

Referring back to FIG. 2B, the container retainer assembly 252 includes (i) includes two pairs of opposed, adjustable X container retainers 260A (only one pair is illustrated in FIG. 2B) that inhibit movement of the first container 246 along the X axis, and about the Z axis; (ii) one pair of opposed, adjustable Y container retainers 260B (only one is illustrated in phantom in FIG. 2B) that inhibits movement of the first container 246 along the Y axis; and (iii) three pairs of opposed, Z container retainers 288 (only two pairs are illustrated in FIG. 2B) that inhibit movement of the first container 246 relative to the second container 250 along the Z axis, about the X axis and about the Y axis. It should be noted that one or more of adjustable X container retainers 260A and/or the adjustable Y container retainers 260B can also be referred to as the adjustable container retainer 260.

The design of each of the adjustable container retainers 260 can vary. In FIG. 2B, each of the adjustable container retainers 260 includes a retainer section 286A and a retainer lock 286B. Alternatively, one or more of the adjustable container retainers 260 can have another design.

In one embodiment, for each of the adjustable container retainers 260, the retainer section 286A extends between the second container 250 and the first container 246, and the retainer section 286A is generally right cylindrical beam shaped and extends through a container aperture in one of the side walls 258B of the second container 250. In this embodiment, movement of each retainer section 286A is guided by the respective side wall 258B. Further, in FIG. 2B, the retainer section 286A includes a distal end 286D that engages the first container 246 and a proximal end 286E that is positioned outside the second container 250. Moreover, in FIG. 2B, the distal end 286D can include a contact area 286F that reduces the likelihood that the distal end 286D will damage the first container 246. For example, the contact area 286F can include a piece of resilient material.

In certain embodiments, the retainer section 286A is selectively movable between an engaged position 287A in which the retainer section 286A engages the first container 246 and a disengaged position 287B (illustrated in FIG. 2F) in which the retainer section 286A does not engage the first container 246.

The retainer lock 286B selectively locks the retainer section 286A to the second container 250 and selectively allows the retainer section 286A to be moved relative to the first container 246 and the second container 250. Stated in another fashion, the retainer lock 286B allows the retainer section 286A to be moved to between the engaged position 287A and the disengaged position 287B and subsequently locked in place at either position. With this design, the retainer sections 286A are maintained in the engaged position 287A during shipping, and the retainer lock 286B provides high stiffness so that no shifting or slipping occurs when the reticle 26 and the container assembly 30 experience high accelerations.

The design of the retainer lock 286B can vary. In one embodiment, the retainer lock 286B does not require power, air of other utilities when in locked state. As a result thereof, the reticle 26 can be securely retained during shipping or storage without external power. In FIG. 2B, the retainer lock 286B includes a clamp 286H and clamp mover 2861 that are secured to the second container 250. For example, the clamp 286H and clamp mover 2861 can be similar in design to the clamp 280H and clamp mover 280I described above.

Additionally, in one embodiment one or more of the adjustable container retainers 260 can include a retainer seal 286S that seals the retainer section 286A to the second container 250 and allows the retainer section 286A to move relative to the second container 250. For example, the second retainer seal 286S can be a bellows type seal.

It should be noted that one or more of the adjustable container retainers 260 can be replaced with a fixed container retainer (not shown) that is fixedly secured to the second container 250.

The design of each of the Z container retainers 288 can vary. In FIG. 2B, each of the Z container retainers 288 that is above the first container 246 is a fixed, right cylindrical shaped beam that extends downward from the second container 250 and each of the Z container retainers 288 that is below the first container 246 is a standoff that extends upward from the bottom wall 258C of the second container 250. In one embodiment, one or more of the Z container retainers 288 includes a contact area 288A that reduces the likelihood that the distal end will damage the first container 246. For example, the contact area 288A can include a piece of resilient material.

It should be noted that one or more of the fixed Z container retainers 288 can be replaced with an adjustable Z container retainer (not shown) that is somewhat similar to the adjustable container retainers 260 described above.

Further, in this embodiment, the upper Z container retainers 288 engage the top of the first container 246. Additional upper Z container retainers (not shown) can be added to the design that engage the bottom wall of the first container 246.

FIG. 2E is a top perspective view of the first container 246 and a simplified illustration of the forces imparted on the first container 246 by (i) the adjustable X container retainers 260A (illustrated as arrows in FIG. 2E) that inhibit movement of the first container 246 along the X axis, and about the Z axis; (ii) the adjustable Y container retainers 260B (illustrated as arrows in FIG. 2E) that inhibit movement of the first container 246 along the Y axis; and (iii) the Z container retainers 288 that inhibit movement to the first container 246 along the Z axis, about the X axis and about the Y axis.

It should be noted that the X container retainers 260A of each pair are aligned along the X axis, the pair of Y container retainers 260B are aligned along the Y axis, and the Z container retainers 288 of each pair are aligned along the Z axis. Further, (i) the X container retainers 260A are perpendicular to the Y container retainers 260B and the Z container retainers 288 and (ii) the Y container retainers 260B are perpendicular to the Z container retainers 288.

Additionally, in this embodiment, three pairs of container retainers 260A, 260B constrain movement of the first container 246 in the horizontal plane so that the first container 246 does not move horizontally. Further, three pairs of container retainers 288 constrain movement of the first container 246 in the vertical plane so that the first container 246 does not move vertically. Alternatively, additionally pairs of container retainers 260A, 260B, 288 can be utilized to decrease the contact force while increasing stiffness and decreasing the required force of the retainer locks 286B.

Moreover, movement of each retainer section 286A (illustrated in FIG. 2B) from the disengaged position 287B to the engaged position 287A occurs substantially perpendicular to the surface of the first container 246 in which that retainer section 286A engages. Stated in another fashion, each retainer section 286A engages the first container 246 with normal contact only (no sliding contact). This reduces the amount of particle generation when the retainer sections 286A engage the first container 246.

Further, with the arrangement illustrated in FIG. 2E, the first container 246 is held by six pairs of retainers 260A, 260B, 288 that are arranged in a kinematic manner. This reduces the likelihood of particle generation caused by relative movement between the first container 246 and the second container 250. Moreover, the amount of force applied by the adjustable container retainers 260A, 260B can be precisely controlled so that the first container 246 is not retained too loosely or too tightly. This further reduces the likelihood of particle generation. Furthermore, because the restraining force does not depend on the friction between the first container 246 and the retainers 260A, 260B, 288, relatively low restraining force can be used and there is less particle generation.

FIG. 2F is a cut-away view of the device 26 and the device container assembly 30 from FIG. 2B with a portion of the device container assembly 30 moved to another position. More specifically, in FIG. 2F, for each device retainer 256, (i) the clamp mover 280I has been moved away from the clamp 280H and the clamp 280H now allows for movement of the retainer section 280A and the retainer mover 280C; and (ii) the retainer section 280A has been moved away from the device 26 to the disengaged position 281B so that the X device retainers 256A and the Y device retainers 256B do not engage the device 26. Further, in FIG. 2F, for each container retainer 260, (i) the clamp mover 2861 has been moved away from the clamp 286H and the clamp 286H now allows for movement of the retainer section 286A; and (ii) the retainer section 286A has been moved away from the first container 246 to the disengaged position 287B so that the X container retainers 260A and the Y container retainers 260B do not engage the first container 246.

FIG. 2G is a cut-away view of the device 26 and the device container assembly 30 from FIG. 2B with a portion of the device container assembly 30 moved to yet another position. More specifically, in FIG. 2G, for each device retainer 256, (i) the clamp mover 280I has been moved against the clamp 280H and the clamp 280H no longer allows for movement of the retainer section 280A; and (ii) the retainer section 280A is locked away in the disengaged position 281B from the device 26 so that the X device retainers 256A and the Y device retainers 256B do not engage the device 26. Further, in FIG. 2G, for each container retainer 260, (i) the clamp mover 2861 has been moved against the clamp 286H and the clamp 286H no longer allows for movement of the retainer section 286A; and (ii) the retainer section 286A is locked away in the disengaged position 287B from the first container 246 so that the X container retainers 260A and the Y container retainers 260B do not engage the first container 246. Further, FIG. 2G illustrates that the pin mover 274 has been rotated so that both lock pins 272 have been moved inward and the lock pins 272 no longer engage the slots 276. With the components in this position, the second removable section 268 can be moved away from the bottom wall 258C.

FIG. 2H is a cut-away view of the device 26 and the device container assembly 30 from FIG. 2B with a portion of the device container assembly 30 moved to still another position. More specifically, in FIG. 2H, the second removable section 268 has been separated from the bottom wall 258C. Further, the X, Y and Z container retainers 260A, 260B, 288 and a portion of the X, Y and Z device retainers 256A, 256B, 282 have been moved with the second removable section 268.

In this position, the first removable section 266 can be separated from the bottom wall 254C to expose the reticle 26. Subsequently, the reticle loader 44 (illustrated in FIG. 1) can move the reticle 26 to the exposure apparatus 10 (illustrated in FIG. 1).

It should be noted that certain embodiments of the device container assembly 30 is compatible with prior art device loaders 44 (illustrated in FIG. 1). Further, the retainers can be engaged and disengaged without opening the first container 246 and the second container 250. Further, the retainers in the disengaged position do not interfere with the mechanisms for opening and closing the containers 246, 250.

Moreover, the adjustable retainers 256, 260 can be moved to the engaged position 281A, 287A prior to shipping and moved to the disengaged position 281B, 287B after shipping is complete. In certain embodiments, after shipping, during handling of the combination 245, only friction is used to inhibit device 26 and the first container 246 from sliding on the lower Z retainers 282, 288 as illustrated in FIG. 2G.

It should be noted that the device container assembly 30 can be re-assembled in the reverse order that is described above.

Further, one or more of the contact areas 280F, 282A, 286F, 288A can include a whiffle-tree structure to decrease stress and/or the contact force. Moreover, one or more the device retainers 256A, 256B, 282, and/or one or more of the container retainers 260A, 260B, 288 can define a conduit that can be used for transferring or removing heat to and from the device 26.

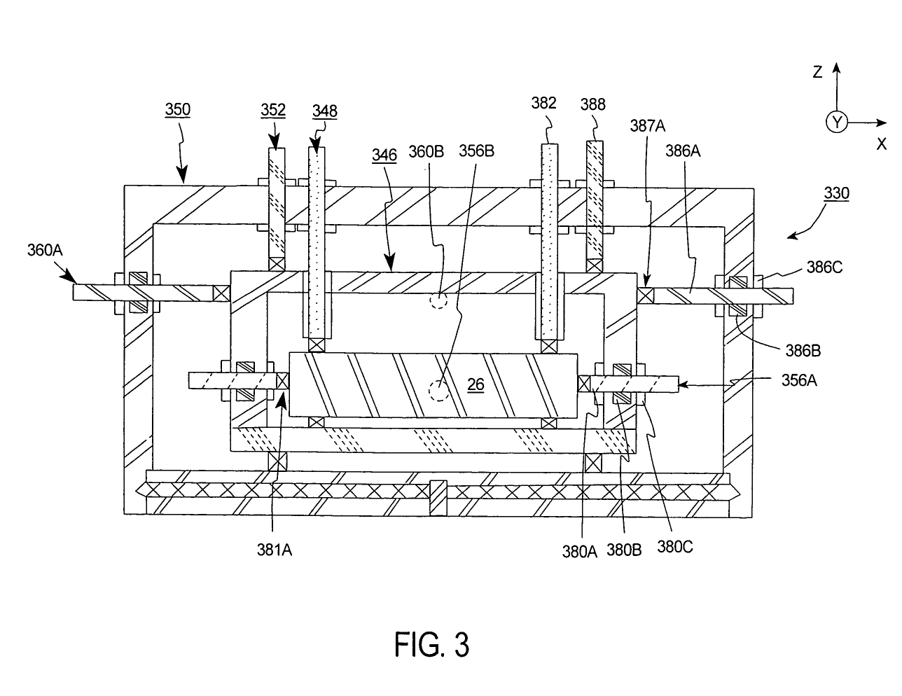

FIG. 3 is a cut-away view of the device 26 and another embodiment of the device container assembly 330. In this embodiment, device container assembly 330 includes (i) a first container 346 and a second container 350 that are similar to the corresponding components described above; and (ii) a device retainer assembly 348, and a container retainer assembly 352 that are slightly different then the corresponding components described above.

In FIG. 3, the device retainer assembly 348 includes (i) two pairs of opposed, X device retainers 356A (only one pair is illustrated in FIG. 3) that inhibit movement of the device 26 relative to the first container 346 along the X axis, and about the Z axis, (ii) one pair of opposed, Y device retainers 356B (only one is illustrated in phantom) that inhibits movement of the device 26 relative to the first container 346 along the Y axis, and (iii) and three spaced part pairs of Z device retainers 382 (only two pairs are illustrated in FIG. 3) that inhibit movement of the device 26 relative to the first container 346 along the Z axis, about the X axis and about the Y axis.

In FIG. 3, some of the device retainers 356A, 356B, 382 are electrically and precisely adjustable. In this embodiment, all of the X device retainers 356A, all of the Y device retainers 356B, and the Z device retainers 382 above the reticle 326 are all electrically controlled. Alternatively, for example, some of the device retainers 356A, 356B, 382 can be manually controlled.

More specifically, in FIG. 3, each of the X device retainers 356A, each the Y device retainers 356B, and each of the upper Z device retainers 382 includes a retainer section 380A that is somewhat similar to the corresponding component described above, a retainer lock 380B, and a retainer actuator 380C. Alternatively, one or more of these device retainers 356A, 356B, 382 can be designed without the retainer lock 380B and/or the retainer actuator 380C.

The retainer lock 380B again selectively locks the retainer section 380A to the first container 346 and selectively allows the retainer section 380A to be moved relative to the first container 346 and the reticle 326. In FIG. 3, the retainer lock 380B is an electronically controlled lock. In one embodiment, the retainer lock 380B is biased to the locked configuration. For example, electrical current can be directed to a ring to heat the ring which expands when heated to allow for movement of the retainer section 380A. Subsequently, when current is removed, the ring shrinks when cooled to contract around the retainer section 380A. For example, the ring can be made of a memory metal alloy steel such as NiTinol. With this design, no current is needed to keep the retainer lock 380B in the locked position.

The retainer actuator 380C can be used to individually and precisely move and position the retainer section 380A against the reticle 326 in the engaged position 381A or away from the reticle 326 in the disengaged position (not shown in FIG. 3). The design of the retainer actuator 380C can include one or more linear motors, rotary motors, voice coil motors, air cylinders, electromagnetic movers, planar motors, or some other type of force mover. In certain embodiments, the retainer actuator 380C can be used to move the device retainers 356A, 356B, 382 in to touch the device 26 with a known, small contact force. This can be accomplished by operating the retainer actuators 380C in force mode. In the force mode, the retainer actuators 380C apply a predetermined maximum force on the device retainers 356A, 356B, 382. Non-exclusive examples of suitable predetermined maximum forces include approximately 0.1, 0.2, 0.3, or 0.4 Newtons. In one embodiment, the predetermined maximum force is slightly greater than the force necessary to move the respective device retainer 356A, 356B, 382. After all of the device retainers 356A, 356B, 382 contact the device 26, the device retainers 356A, 356B, 382 can be locked in position with the retainer lock 380B.

In FIG. 3, the container retainer assembly 352 includes (i) two pairs of opposed, X container retainers 360A (only one pair is illustrated in FIG. 3) that inhibit movement of the first container 346 relative to the second container 350 along the X axis, and about the Z axis, (ii) one pair of opposed, Y container retainers 360B (only one is illustrated in phantom) that inhibits movement of the first container 346 relative to the second container 350 along the Y axis, and (iii) and three spaced part pairs of Z container retainers 388 (only two pairs are illustrated in FIG. 3) that inhibit movement of the first container 346 relative to the second container 350 along the Z axis, about the X axis and about the Y axis.

In FIG. 3, some of the container retainers 360A, 360B, 388 are electrically and precisely adjustable. In this embodiment, all of the X container retainers 360A, all of the Y container retainers 360B, and the Z container retainers 388 above the first container 346 are all electrically controlled. Alternatively, for example, some of the container retainers 360A, 360B, 388 can be manually controlled.

More specifically, in FIG. 3, each of the X container retainers 360A, each the Y container retainers 360B, and each of the upper Z container retainers 388 includes a retainer section 386A that is somewhat similar to the corresponding component described above, a retainer lock 386B, and a retainer actuator 386C. Alternatively, one or more of these device retainers 360A, 360B, 388 can be designed without the retainer lock 386B and/or the retainer actuator 386C.

The retainer lock 386B again selectively locks the retainer section 386A to the second container 350 and selectively allows the retainer section 386A to be moved relative to the second container 350 and the first container 346. In FIG. 3, the retainer lock 386B is an electronically controlled lock. In one embodiment, the retainer lock 386B is biased to the locked configuration. For example, retainer lock 386B can have a design that is similar to the retainer lock 380B described above.

The retainer actuator 386C can be used to individually and precisely move and position the retainer sections 386A against the first container 346 in the engaged position 387A or away from the first container 346 in the disengaged position (not shown in FIG. 3). For example, the retainer actuator 386C can have a design that is similar to the retainer actuator 380C described above.

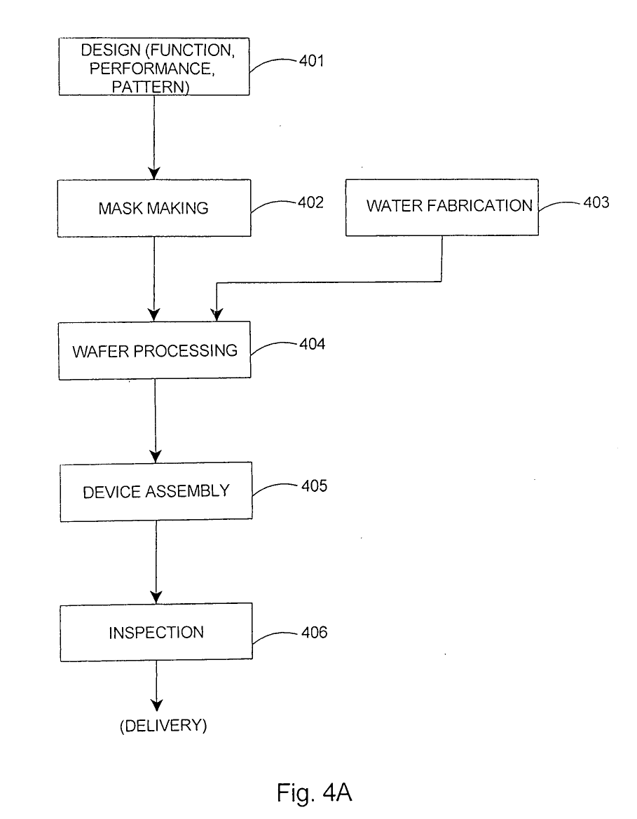

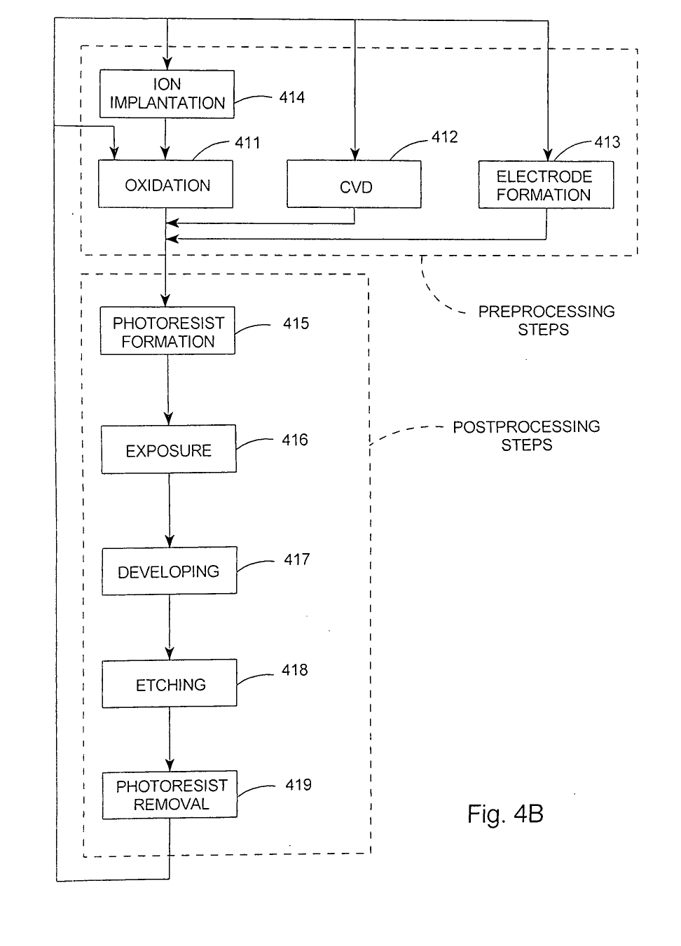

As mentioned above, the device container assemblies 30, 330 described herein can store a reticle 26 that is used for the manufacture of semiconductor wafers 28. Semiconductor devices can be fabricated using the above described systems, by the process shown generally in FIG. 4A. In step 401 the device's function and performance characteristics are designed. Next, in step 402, a mask (reticle) having a pattern is designed according to the previous designing step, and in a parallel step 403 a wafer is made from a silicon material. The mask pattern designed in step 402 is exposed onto the wafer from step 403 in step 404 by a photolithography system described hereinabove in accordance with the present invention. In step 405, the semiconductor device is assembled (including the dicing process, bonding process and packaging process), finally, the device is then inspected in step 406.

FIG. 4B illustrates a detailed flowchart example of the above-mentioned step 404 in the case of fabricating semiconductor devices. In FIG. 4B, in step 411 (oxidation step), the wafer surface is oxidized. In step 412 (CVD step), an insulation film is formed on the wafer surface. In step 413 (electrode formation step), electrodes are formed on the wafer by vapor deposition. In step 414 (ion implantation step), ions are implanted in the wafer. The above mentioned steps 411-414 form the preprocessing steps for wafers during wafer processing, and selection is made at each step according to processing requirements.

At each stage of wafer processing, when the above-mentioned preprocessing steps have been completed, the following post-processing steps are implemented. During post-processing, first, in step 415 (photoresist formation step), photoresist is applied to a wafer. Next, in step 416 (exposure step), the above-mentioned exposure device is used to transfer the circuit pattern of a mask (reticle) to a wafer. Then in step 417 (developing step), the exposed wafer is developed, and in step 418 (etching step), parts other than residual photoresist (exposed material surface) are removed by etching. In step 419 (photoresist removal step), unnecessary photoresist remaining after etching is removed.

Multiple circuit patterns are formed by repetition of these preprocessing and post-processing steps.

While the particular assembly as herein shown and disclosed in detail is fully capable of obtaining the objects and providing the advantages herein before stated, it is to be understood that it is merely illustrative of the presently preferred embodiments of the invention and that no limitations are intended to the details of construction or design herein shown other than as described in the appended claims.

What is claimed is:

1. A device container assembly for storing a device, the device container assembly comprising:
a first container that encircles the device; and
a device retainer assembly that selectively couples the device to the first container, the device retainer assembly including an adjustable first device retainer having a retainer section that is movable relative to the first container between an engaged position in which the retainer section engages the device and a disengaged position in which the retainer section does not engage the device.

2. The device container assembly of claim 1 wherein the first device retainer includes a retainer lock that selectively locks the retainer section in at least one of the positions.

3. The device container assembly of claim 1 wherein the first device retainer includes a retainer actuator that moves the retainer section between the disengaged position and the engaged position.

4. The device container assembly of claim 3 wherein the retainer actuator is operated in a force mode.

5. The device container assembly of claim 3 wherein the first device retainer includes a retainer lock that selectively locks the retainer section in at least one of the positions.

6. The device container assembly of claim 1 wherein the retainer section engages the device with substantially normal contact.

7. The device container assembly of claim 1 wherein the retainer section is moved between the positions with the first container encircling the device.

8. The device container assembly of claim 1 wherein the device retainer assembly includes an adjustable second device retainer having a retainer section that is movable relative to the first container between an engaged position in which the retainer section engages the device and a disengaged position in which the retainer section does not engage the device; and wherein the retainer section of the second device retainer is substantially aligned with and opposite from the retainer section of the first device retainer.

9. The device container assembly of claim 1 wherein the device retainer assembly includes an adjustable second device retainer having a retainer section that is movable relative to the first container between an engaged position in which the retainer section engages the device and a disengaged position in which the retainer section does not engage the device; and wherein the retainer section of the second device retainer is substantially parallel to and spaced apart from the retainer section of the first device retainer.

10. The device container assembly of claim 1 wherein the device retainer assembly includes an adjustable second device retainer having a retainer section that is movable relative to the first container between an engaged position in which the retainer section engages the device and a disengaged position in which the retainer section does not engage the device; and wherein the retainer section of the second device retainer is substantially perpendicular to and spaced apart from the retainer section of the first device retainer.

11. The device container assembly of claim 1 wherein the device retainer assembly includes six device retainer pairs that cooperate to secure the device in a kinematic fashion.

12. The device container assembly of claim 1 further comprising (i) a second container that encircles the first container, and (ii) a container retainer assembly that selectively couples the first container to the second container, the container retainer assembly including an adjustable container retainer having a retainer section that is movable relative to the second container between an engaged position in which the retainer section engages the first container and a disengaged position in which the retainer section does not engage the first container.

13. The device container assembly of claim 12 wherein the container retainer includes a retainer lock that selectively locks the retainer section in at least one of the positions.

14. The device container assembly of claim 12 wherein the container retainer includes a retainer actuator that moves the retainer section between the disengaged position and the engaged position.

15. The device container assembly of claim 12 wherein the device container assembly includes six container retainer pairs that cooperate to secure the first container in a kinematic fashion.

16. A combination including a reticle and the device container assembly of claim 1 storing the reticle.

17. An exposure apparatus for transferring an image to an object, the exposure apparatus comprising, the combination of claim 16, a reticle stage assembly that positions the reticle, and a reticle loader that moves the reticle between the device container and the reticle stage assembly.

18. A method for manufacturing an object, the method comprising the steps of providing a substrate, and transferring an image to the substrate with the exposure apparatus of claim 17.

19. A device container assembly for storing a device, the device container assembly comprising:
a first container that encircles the device;
a second container that encircles the first container; and
a container retainer assembly that selectively couples the first container to the second container, the container retainer assembly including an adjustable first container retainer having a retainer section that is movable relative to the second container between an engaged position in which the retainer section engages the first container and a disengaged position in which the retainer section does not engage the first container.

20. The device container assembly of claim 19 wherein the first container retainer includes a retainer lock that selectively locks the retainer section in at least one of the positions.

21. The device container assembly of claim 19 wherein the first container retainer includes a retainer actuator that moves the retainer section between the disengaged position and the engaged position.

22. The device container assembly of claim 19 wherein the retainer section is moved between the positions with the first container encircling the device and the second container encircling the first container.

23. The device container assembly of claim 19 wherein the container retainer assembly includes an adjustable second container retainer having a retainer section that is movable relative to the second container between an engaged position in which the retainer section engages the first container and a disengaged position in which the retainer section does not engage the first container; and wherein the retainer section of the second container retainer is substantially aligned with and opposite from the retainer section of the first container retainer.

24. The device container assembly of claim 19 wherein the container retainer assembly includes an adjustable second container retainer having a retainer section that is movable relative to the second container between an engaged position in which the retainer section engages the first container and a disengaged position in which the retainer section does not engage the first container; and wherein the retainer section of the second container retainer is substantially perpendicular to and spaced apart from the retainer section of the first device retainer.

25. The device container assembly of claim 19 wherein the container retainer assembly includes six container retainer pairs that cooperate to secure the first container in a kinematic fashion.

26. The device container assembly of claim 19 further comprising a device retainer assembly that selectively couples the device to the first container, the device retainer assembly including (i) an adjustable device retainer having a retainer section that is movable relative to the first container between an engaged position in which the retainer section engages the device and a disengaged position in which the retainer section does not engage the device, and (ii) a retainer lock that selectively locks the retainer section of the device retainer in at least one of the positions.

27. A combination including a reticle and the device container assembly of claim 19 storing the reticle.

28. An exposure apparatus for transferring an image to an object, the exposure apparatus comprising, the combination of claim 27, a reticle stage assembly that positions the reticle, and a reticle loader that moves the reticle between the device container and the reticle stage assembly.

29. A method for manufacturing an object, the method comprising the steps of providing a substrate, and transferring an image to the substrate with the exposure apparatus of claim 28.

30. A method for storing a device, the method comprising the steps of:
enclosing the device in a first container; and
moving a retainer section of a device retainer from a disengaged position in which the retainer section does not engage the device to an engaged position in which the retainer section engages the device.

31. The method of claim 30 further comprising the step of locking the retainer section in at least one of the positions.

32. The method of claim 30 wherein the step of moving includes the step of moving the retainer section with a retainer actuator.

33. The method of claim 30 further comprising the steps of encircling the first container with a second container, and moving a retainer section of a container retainer from a disengaged position in which the retainer section does not engage the first container to an engaged position in which the retainer section engages the first container.

34. A method for transferring an image to a substrate, the method comprising the steps of storing the device by the method of claim 30, providing a reticle stage assembly that positions the device, moving the device between the first container and the reticle stage assembly with a device loader, and irradiating the device to transfer the image to the substrate.
